(19) United States
(12) Patent Application Publication
(10) Pub. No.: US 2002/0079449 A1
(43) Pub. Date: Jun. 27, 2002

(54) SEM having a detector surface segmented into a number of separate regions

(76) Inventors: Marcellinus Petrus Carolus Michael Krijn, Eindhoven (NL); Jan Martijn Krans, Eindhoven (NL)

Correspondence Address: U.S. Philips Corporation, 580 White Plains Road, Tarrytown, NY, 10591, US

(21) Appl. No.: 10/011,618

(22) Filed: Dec. 6, 2001

(30) Foreign Application Priority Data
Dec. 11, 2000 (EP) 00204432.9

(51) Int. Cl. H01J 37/28; H01J 37/244

(52) U.S. Cl. 250/310; 250/397

(57) ABSTRACT

The invention relates to a SEM with an electrostatic objective lens 14, 16 and a detector 6, 8 for through-the-lens detection of electrons 24. In accordance with the invention a voltage contrast (voltage range of the order of magnitude of from 1 to 10 V) is achieved by subdividing this detector surface 9 into separate regions, preferably concentric annular regions 36 and 38, and by electronically combining the signals from these regions.

The invention relates to a particle-optical apparatus which includes

a particle source for producing a primary beam of electrically charged particles which travel along an optical axis of the apparatus,

a specimen holder for a specimen to be irradiated by means of the apparatus,

a focusing device for forming a focus of the primary beam in the vicinity of the specimen holder by means of electrostatic electrodes,

a detector surface for detecting electrically charged particles which emanate from the specimen in response to the incidence of the primary beam, which detector surface is arranged ahead of the focusing device, viewed in the propagation direction of the electrically charged particles in the primary beam.

An apparatus of this kind is known from the published international patent application WO 99/34397. In the apparatus described therein a region of a specimen to be examined is scanned by means of a focused primary beam of electrically charged particles, usually electrons, which travel along an optical axis of the apparatus. An apparatus of this kind is known as a Scanning Electron Microscope (SEM).

Irradiation of the specimen to be examined releases electrically charged particles (such as secondary electrons) from the specimen; such secondary electrons have an energy which is substantially lower, for example of the order of magnitude of from 1 to 10 eV, than the energy of the primary beam. The energy and/or the energy distribution of such secondary electrons offers information as regards the nature and the composition of the specimen. Therefore, a SEM is advantageously provided with a detection device (detector) for secondary electrons. These electrons are released at the side of the specimen where the primary beam is incident, after which they travel back against the direction of incidence of the primary electrons. When a detector (for example, provided with an electrode carrying a positive voltage) is arranged in the path of the secondary electrons thus traveling back, the second electrons are captured by this electrode and the detector outputs an electric signal which is proportional to the electric current thus detected. The (secondary electron) image of the specimen is thus formed in known manner. The detector in the known particle-optical apparatus is formed by a detector crystal of cerium-doped yttrium aluminum garnet (YAG) which produces a light pulse in response to the capture of an electron of sufficient energy, which light pulse is converted into an electric signal wherefrom an image of the specimen can be derived. The detector crystal is provided with a bore to allow passage of the primary beam. The surface facing the secondary electrons is the detector surface for the detection of electrically charged particles that emanate from the specimen in response to the incidence of the primary beam.

Nowadays there is a tendency to construct SEMs to be as small as possible. Apart from economical motives (generally speaking, smaller apparatus can be more economically manufactured), such small apparatus offer the advantage that, because of their mobility and small space required, they can be used not only as a laboratory instrument but also as a tool for the formation of small structures, for example as in the production of integrated circuits. In this field a miniaturized SEM can be used for direct production as well as for inspection of products. With a view to direct production, the SEM can be used to write, using electrons, a pattern on the IC to be manufactured. With a view to inspection, the SEM can be used to observe the relevant process during the writing by means of a further particle beam (for example, an ion beam for implantation in the IC to be manufactured); it is also possible to use the SEM for on-line inspection of an IC after completion of a step of the manufacturing process.

For miniaturization of a SEM it is attractive to use an electrostatic objective, because such an objective can be constructed so as to be smaller than a magnetic lens. This is due to the fact that cooling means (notably cooling ducts for the lens coil) can be dispensed with and that the magnetic (iron) circuit of the lens requires a given volume in order to prevent magnetic saturation. Moreover, because of the contemporary requirements as regards high vacuum in the specimen space, electrostatic electrodes (which are constructed as smooth metal surfaces) are more attractive than the surfaces of a magnetic lens which are often provided with coils, wires and/or vacuum rings. Finally, as is generally known in particle optics, an electrical field is a more suitable lens for heavily particles (ions) than a magnetic field. The objective in the known SEM has two electrostatic electrodes which together form a decelerating system for the primary beam.

The arrangement of the detector for the secondary electrons ahead of the focusing device in the known SEM offers the advantage that when the SEM is used for the inspection of ICs, it is also easier to look into pit-shaped irregularities; this is because observation takes place along the same line as that along which the primary beam is incident. Moreover, arranging a detector to the side of the objective and directly above the specimen would have the drawback that the detector would then make it impossible for the distance between the objective and the specimen to be made as small as desirable with a view to the strong reduction of the electron source so as to achieve a size of the scanning electron spot which is sufficiently small with a view to the required resolution. Furthermore, when an electrostatic objective is used in an SEM, it often happens that the electrostatic lens field of the objective extends beyond the physical boundaries of the objective, so possibly as far as the specimen. (This electrical field between the final electrode of the objective and the specimen is also referred to as the leakage field). Because of the presence of the leakage field, secondary electrons emanating from the specimen would be attracted by this field. For example, a detector arranged to the side of the objective would then require a much stronger attractive effect whereby the primary beam would be inadmissibly influenced. This adverse effect is avoided by arranging the detector above the objective. When the secondary electrons attracted by the leakage field have passed through the bore of the objective, they are accelerated, by the electrical field present therein, to an energy value that corresponds to the potential in the space ahead of the objective. The electrons thus accelerated now have sufficient energy to excite the detector material, thus enabling detection.

During the examination of a specimen it is often desirable to observe voltage contrast, meaning that regions of the specimen that have a mutually different potential (for example, of the order of magnitude of some volts) exhibit a different intensity in the image, so that contrast arises between said regions in the image. This is desirable notably for the inspection of integrated circuits in which the presence of defects becomes manifest as the presence or absence of voltage differences in the circuit.

The contrast arises as follows. As is known, most secondary electrons emanating from the surface of the specimen have an energy of between 0 and 10 eV. It is possible to compare the situations in which secondary electrons emanate from a region on the specimen with a potential of, for example zero volts and the situations in which they emanate from a region with a potential of, for example 5 V. After emanating from the specimen surface, the secondary electrons are accelerated in the direction of the detector surface which carries a given (positive) potential relative to the specimen. When they reach the detector surface, the secondary electrons that originate from the region of 0 V will have an energy that corresponds to the sum of their initial energy (so an amount between 0 and 10 eV) Eₑ and the energy Eₚ obtained by traversing the potential difference between the specimen and the detector surface. When they reach the detector surface, the secondary electrons that emanate from the region with 5 V will also have a speed that corresponds to the sum of their initial energy and the energy obtained by traversing the potential difference. In the latter case, however, the potential difference overcome is 5 V lower than in the first case. In order to make this energy difference, that is, the voltage contrast, visible in a SEM image, the detector must be capable of discriminating the secondary electrons of different energies, that is, even when they originate from the same point of the specimen. This cannot be done by means of the detector in the known SEM.

It is an object of the invention to provide a particle-optical apparatus of the kind set forth in which voltage contrast can be made visible in a SEM image even when the electrons originate from the same point of the specimen. To this end, the apparatus in accordance with the invention is characterized in that the detector surface is segmented into a number of mutually separated regions. The invention is based on the following insight. The secondary electrons to be detected arrive at different points of incidence on the detector surface, that is, in dependence on the location on the specimen wherefrom they originate, on their initial energy and on the angle at which they emanate from the specimen. The paths of these electrons are influenced by the accelerating field that is present within the objective electrodes and by the deflection fields that are required for the scanning of the primary beam and are also traversed by the secondary electron beam, so that it is not clear a priori where the electrons originating from a given point on the specimen will be incident. However, the electrons that emanate from a point and have the same energy and, moreover, emanate from the specimen at the same angle will practically always be incident in approximately the same point on the detector surface, whereas electrons that emanate from the same point and at the same angle but with a different energy will land at a different point on the detector surface. This is particularly important in the case of electrons that originate from a pit-like recess on the specimen as is often the case in integrated circuits. These electrons will emanate from the specimen surface at approximately right angles. Because the detector surface is segmented into different regions, a distinction can thus be made between electrons that emanate from the same point with different energies; this means that voltage contrast is obtained. Moreover, the invention enables mono-energetic electrons to be discriminated in respect of exit angle.

The mutually separated regions in a preferred embodiment of the invention are formed by concentric annular parts. This embodiment of the invention is based on the insight that when the point of departure of the secondary electrons of the specimen is situated on the optical axis, the landing spots of these electrons will be situated symmetrically around the optical axis on the detector surface. The distance from the optical axis is then determined by the angle at which the secondary electrons leave the specimen and also by their energy. Electrons having a comparatively low energy (for example, 1 eV) land within a comparatively small circle around the optical axis, whereas electrons having a comparatively high energy (for example, 5 eV) land within a significantly larger circle around the optical axis. For many applications, for example, the inspection or treatment of integrated circuits, the point of departure of the secondary electrons is situated very near to the optical axis. This is due to the fact that the highest possible resolution of a SEM is obtained only by means of the primary beam on the specimen in the vicinity of the optical axis. Because very small defects have to be detected in the case of wafer inspection, such a highest attainable resolution is necessary so that for wafer inspection the region to be inspected is moved to the area of the optical axis.

According to this method of imaging, the fraction of high-energetic electrons in the intermediate region between the small circle and the large circle is much larger than that in the inner region of the small circle. The voltage contrast can be made visible by combining the currents of these two regions linearly (made possible by the fact that the detector surface is segmented into a number of annular regions in accordance with the invention). The voltage contrast can be adjusted to a maximum value by varying the coefficients to be used for this linear combination, so that these coefficients can be experimentally determined for maximum voltage contrast. The dimensions of the annular parts of the detector surface can also be experimentally optimized for maximum voltage contrast.

The boundary lines between the mutually separated regions in an embodiment of the invention are formed by straight lines that extend through the point of intersection of the optical axis and the detector surface. Detection in this embodiment can make a distinction between electrons that leave the specimen at different angles or with different angular distributions. This is notably the case for integrated circuits which exhibit, for example a threshold-like raised portion. When the primary beam is incident on the edge of the threshold, the angular distribution of the secondary electrons then released will not be circular symmetrical. The straight lines through the center of the detector subdivide the detector surface into sector-like parts (for example, two or four parts). This sector-like distribution enables, while moving around the primary beam, a distinction to be made between a first angular region with a high electron density and a second angular region with a lower electron density, thus enabling directional contrast to be obtained.

The invention will be described in detail hereinafter with reference to the Figures in which corresponding reference numerals denote corresponding elements. Therein:

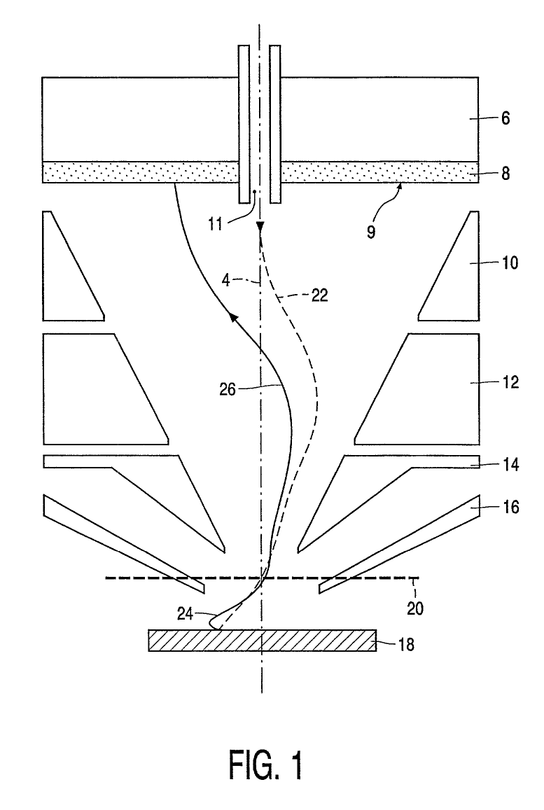

FIG. 1 is a diagrammatic representation of a relevant part of a particle-optical apparatus in accordance with the invention;

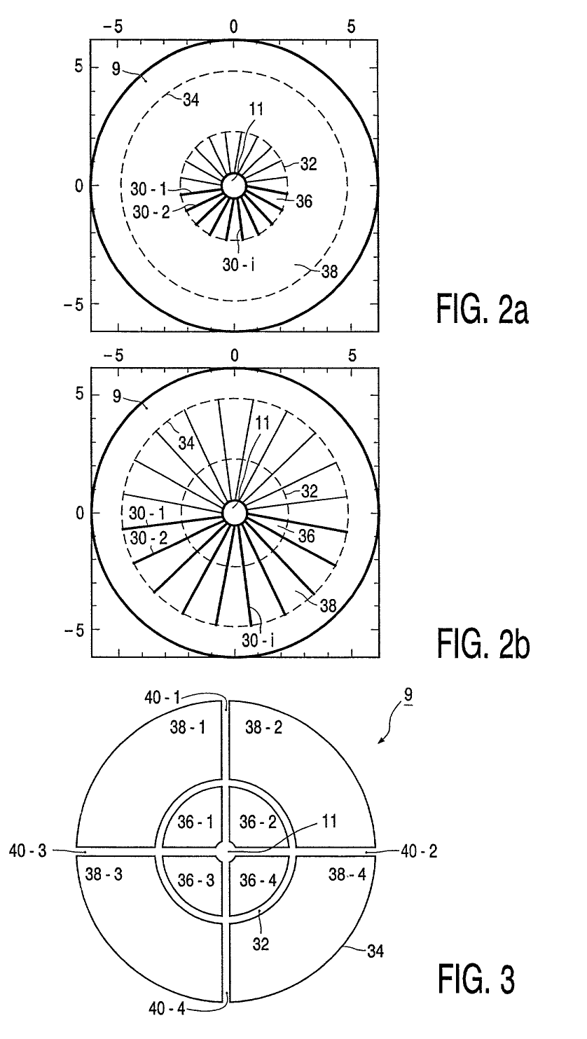

FIGS. 2a and 2b illustrate the landing locations of secondary electrons with different angles of departure for two different energies;

FIG. 3 is a representation of a detector surface plate with two concentric annular regions in combination with a sector-like segmentation.

FIG. 1 shows a relevant part of a SEM in accordance with the invention. In as far as they are not relevant to the invention, the electron source and all further elements that form part of the electron optical column and serve to accelerate and control the primary beam are not shown. The primary beam, which is not shown in FIG. 1, travels along the optical axis 4 of the SEM. The primary beam thus successively traverses a detector crystal 6, an electrostatic acceleration electrode 8, a first electrical deflection electrode 10, a second electrical deflection electrode 12, a first electrostatic electrode 14 which forms part of the objective, and a second electrostatic electrode 16 which also forms part of the objective. Finally, the electrons of the primary beam reach the specimen 18 to be inspected or worked.

The detector crystal 6 forms part of detection means for the detection of electrons that emanate from the specimen in response to the incidence of the primary beam. This detector crystal consists of a substance (for example, cerium-doped yttrium aluminum garnet or YAG) which produces a light pulse in response to the capture of an electron of adequate energy (a scintillator crystal); this light pulse is conducted further by means of optical guide means (not shown) and is converted, in an opto-electric transducer, into an electrical signal wherefrom an image of the specimen can be derived, if desired. The latter elements also form part of said detection means. The detector crystal 6 is provided with a detector surface 9 and with a bore for the passage of the primary beam.

The electrostatic acceleration electrode 8 forms part of the electrode system 8, 14, 16, the electrodes 14 and 16 of which constitute the objective of the SEM which serves to focus the primary beam. The electrode 8 is shaped as a flat plate which is provided with a bore 11 for the primary beam and is deposited on the detection material in the form of a conductive oxide, for example indium oxide and/or tin oxide, that is, notably on the detection surface 9 of the scintillation crystal 6. The electrode 8 can be adjusted to a desired voltage of, for example, 9 kV by means of a power supply unit (not shown).

The first electrical deflection electrode 10 and the second electrical deflection electrode 12 form part of a beam deflection system for deflecting the primary beam. Each of these two electrodes is constructed as a tubular portion that has an external shape in the form of a straight circular cylinder and an internal shape in the form of a cone which is tapered in the direction of the beam. Each of the electrodes 10 and 12 is subdivided into four equal parts by way of two saw cuts in mutually perpendicular planes through the optical axis, so that each of the electrodes 10 and 12 is capable of producing electrical dipole fields in the x direction as well as in the y direction by application of suitable voltage differences between the portions, with the result that the primary beam can be deflected across the specimen 18 and the path of the secondary electrons that move in the direction of the detector crystal can be influenced. Instead of subdividing the electrodes 10 and 12 into four parts, they can also be subdivided into a larger number of parts, for example eight equal parts, by means of four saw cuts in a plane through the optical axis. When the appropriate voltages are applied to the various parts of each of the electrodes, the system thus formed can be used not only for deflecting the beam but also as a stigmator.

The first electrode 14 and the second electrode 16 constitute the electrode system which forms the objective of the SEM. Internally as well as externally the electrode 14 is shaped as a cone which is tapered downwards, so that the electrode fits within the electrode 16. Internally as well as externally the electrode 16 is also shaped as a cone which is tapered downwards; the external conical shape offers optimum space for the treatment of comparatively large specimens such as circular wafers which are used for the manufacture of ICs and may have a diameter of 300 mm. Because of the external conical shape of the electrode 16, the primary beam can be made to strike the wafer at a comparatively large angle by tilting the wafer underneath the objective, without the wafer experiencing interference from parts that project from the objective. A dashed line 20 in the Figure indicates the region in which the lens effect of the electrical objective field (so the paraxial center of the objective) can be assumed to be localized.

The objective 14, 16 focuses the primary beam in such a manner that the electron source is imaged on the (grounded) specimen with a generally very large reduction; because of this strong reduction, the distance between the surface of the specimen 18 and the center of the lens 20 (the focal distance) is very small which, as has already been mentioned, would severely limit the possibility of tilting if the external shape of the electrode 16 were not conical.

The Figure shows the course of some electron paths in the particle-optical instrument. The course of these paths has been obtained by way of computer simulation; the following assumptions were made for this simulation: the voltage whereby the primary beam is accelerated amounted to 10 kV; the energy of the secondary electron is 1 eV; the specimen is grounded; the voltage V_{d} at the detector amounts to 9 kV; the voltages at the electrode 10 are 9+2=11 kV and 9−2=7 kV; the voltages at the electrode 12 are 9−1.8=7.2 kV and 9+1.8=10.8 kV. For the electron paths as represented in the Figure the electrode 16 carries the same potential as the specimen 18.

The primary beam 22 (only diagrammatically represented by a dashed line in this Figure) that enters the assembly formed by the detector, the deflection electrodes and the objective initially travels along the optical axis 4. Under the influence of the electrical deflection field that is generated by the electrode 10, the beam is deflected away from the axis after which it is deflected towards the axis again under the influence of the opposed deflection field that is generated by the electrode 12. As a result, the primary beam intersects the optical axis far below the deflection electrodes 10 and 12. As a result of the arrangement of the beam deflection system and the fact that this system operates with two opposite fields it is achieved that the tilting point is situated in the central plane 20 of the objective, so that a large field of view and a minimum imaging error are achieved, regardless of the magnitude of the scanning motion of the primary beam. This phenomenon can be clearly observed in the Figure which shows that, after deflection by the deflection fields, the primary beam intersects the optical axis 4 in the central plane 20.

The incidence of the primary beam 22 on the specimen 18 releases secondary electrons from the specimen; these secondary electrons travel upwards under the influence of the electrical field of the objective, of the deflection system and of the detector voltage. The Figure shows a path 24 of such a secondary electron. The secondary electron is pulled into the bore of the objective, after which it becomes subject to the deflector fields. The Figure illustrates the effect of the electrical deflection fields by way of the path 26.

FIGS. 2a and b are graphic representations of the landing spots of secondary electrons with different angles of departure for two different energies. The Figures have been obtained by computer simulation of the paths of the secondary electrons. A secondary electron energy of 1 eV was assumed for FIG. 2a and a secondary electron energy of 5 eV for FIG. 2b. The following values of the imaging parameters were adjusted for drafting these Figures: the voltage on the acceleration electrode 8 of the detector amounted to 9 kV; the voltage on the deflection electrodes 10 and 12 amounted to 9 kV (so no actual deflection took place for the drafting of the FIGS. 2a and 2b); the voltage at the objective electrodes 14 and 15 amounted to 11 kV and 0 V, respectively; the distance between the objective electrode 16 and the specimen 18 amounted to 2.5 mm. For both FIGS. 2a and 2b it is assumed that the point of departure of the secondary electrons from the specimen surface 18 is formed by the point of intersection of the optical axis 4 and the specimen 18. The variable quantities in these Figures are the angle [symbol] at which the secondary electrons leave the specimen relative to the specimen surface 18, and the angle φ relative to a ray of fixed direction in the specimen 18 and that passes through the optical axis 4. In both Figures the distance is given in millimeters, that is, in the horizontal (x) direction as well as in the vertical (y) direction.

The line 30-1 in FIG. 2a is formed by the set of landing spots on the detector surface 9 for which the angle φ has a value of 0° and for which the value of the angle [symbol] varies between 0° and 90°. It is to be noted that for the value [symbol] =0° and φ=0° the landing spot is situated at the center of the Figure, that is, in this case in the bore 11 for passage of the primary beam. Because of the small step size, the various points apparently form an uninterrupted line. All further lines 30-i are obtained by step-wise incrementing the value of the angle φ; in FIG. 2a the step size amounts to 18°. The line 30-2 is thus formed by the set of landing spots on the detector surface 9 for which the angle p has a value of 18° and for which the value of the angle [symbol] again varies between 0° and 90°. FIG. 2a clearly shows that the landing spots of the secondary electrons that leave the specimen surface with an energy of 1 eV are all situated in a region that is bounded by the dashed line 32.

FIG. 2b has been obtained in the same way as FIG. 2a; the only difference between the two Figures resides in the fact that the secondary electrons in FIG. 2b leave the specimen surface with an energy of 5 eV. FIG. 2b clearly shows that the landing spots of these secondary electrons are all situated in a region that is bounded by the dashed line 34.

A comparison of the two FIGS. 2a and 2b shows that only the high-energetic secondary electrons are incident in the region between the dashed lines 32 and 34. If the detector surface 9 were subdivided into two mutually separated parts in conformity with the dashed line 32, two concentric, ring-shaped parts 36 and 38 would be formed. The current originating from the ring 38 then corresponds to an electron energy of 5 eV whereas the current originating from the ring 36 is formed by electrons having an energy of 1 eV as well as electrons having an energy of 5 eV.

The voltage contrast Cᵥ in the image can now be obtained by linearly combining the currents I₁ and I₂ from the regions 36 and 38, respectively, for example in conformity with Cᵥ=(I₁−c.I₂)/(I₁+I₂), where c is a constant that is to be experimentally determined in order to optimize the voltage contrast. The determination of this constant can be performed, for example by irradiating the detector surface 9 by means of an electron beam of known energy composition. The ratio of the high-energetic current to the low-energetic current can then be determined (once), thus determining the constant c. However, it is alternatively possible to assume the value c=1. The above relation between the two currents for realizing the voltage contrast offers the advantage that the voltage contrast in that case is not dependent on the total beam current. When the beam current varies by a given factor, this factor will occur in the numerator as well as in the denominator and hence will be eliminated by the division. A (strong) variation of the beam current may occur, for example, because a region of the specimen has a different material composition, and hence possibly a different secondary emission factor, in comparison with another region.

FIG. 3 is a representation of a detector surface with two concentric ring-shaped regions which, moreover, are subdivided into four sectors of circle. The inner ring and the outer ring correspond to the region 36 and the region 38, respectively, in FIG. 2 while the separation between the ring-shaped regions is realized by way of the saw cut 32 which corresponds to the dashed line 32 in FIG. 2. The separation between the four sector-like regions 36-1, 36-2, 36-3 and 36-4 and 38-1, 38-2, 38-3 and 38-4, respectively, is realized by way of the straight lines 40-1, 40-2, 40-3 and 40-4 which extend through the point of intersection of the optical axis 4 and the detector surface 9, that is, through the center of the bore 11.

If the detector crystal is formed by a scintillator crystal, the light pulses generated therein are conducted, via optical conductors (not shown), to an opto-electric converter in which they are converted into an electric signal wherefrom an image of the specimen can be derived. However, it is to be noted that non-optical detectors are also feasible, for example, a semiconductor detector.

1. A particle-optical apparatus which includes
a particle source for producing a primary beam (22) of electrically charged particles which travel along an optical axis (4) of the apparatus,
a specimen holder for a specimen (18) to be irradiated by means of the apparatus,
a focusing device (14, 16) for forming a focus of the primary beam in the vicinity of the specimen holder by means of electrostatic electrodes,
a detector surface (9) for detecting electrically charged particles which emanate from the specimen in response to the incidence of the primary beam, which detector surface (9) is arranged ahead of the focusing device, viewed in the propagation direction of the primary beam, characterized in that the detector surface (9) is segmented into a number of mutually separated regions.

2. A particle-optical apparatus as claimed in claim 1, wherein the mutually separated regions are formed by concentric, annular parts (36, 38).

3. A particle-optical apparatus as claimed in claim 1 or 2, wherein the boundary lines between the mutually separated regions are formed by straight lines that extend through the point of intersection of the optical axis (4) and the detector surface (9).
